(19) United States
(12) Patent Application Publication
(10) Pub. No.: US 2024/0219844 A1
(43) Pub. Date: Jul. 4, 2024

(54) METHOD AND APPARATUS FOR DETERMINING OPTICAL PROPERTIES OF DEPOSITION MATERIALS USED FOR LITHOGRAPHIC MASKS

(71) Applicant: Carl Zeiss SMT GmbH, Oberkochen (DE)

(72) Inventors: Nicole Auth, Ginsheim-Gustavsburg (DE); Michael Budach, Hanau (DE); Christian Felix Hermanns, Frankfurt am Main (DE); Fan Tu, Dieburg (DE)

(21) Appl. No.: 18/426,549

(22) Filed: Jan. 30, 2024

Related U.S. Application Data
(63) Continuation-in-part of application No. PCT/EP21/71490, filed on Jul. 30, 2021.

(51) Int. Cl. G03F 7/00; G03F 1/54

(52) U.S. Cl. CPC G03F 7/70608; G03F 1/54; G03F 7/70958

(57) ABSTRACT

The present invention refers to a method for determining at least one optical property of at least one deposition material used for a lithographic mask which comprises the steps: (a) determining a height value of the at least one deposition material deposited on a substrate for each of at least three different deposition heights of the deposition material, wherein the at least three different deposition heights are in a nanoscale range; (b) determining a reflectivity value of the at least one deposition material for each of the at least three different deposition heights, wherein determining the reflectivity values comprises using photons generated by an optical inspection system; and (c) determining the at least one optical property of the at least one deposition material by adapting simulated reflectivity data to the measured reflectivity values for each of the at least three different deposition heights.

### CROSS-REFERENCE TO RELATED APPLICATION

This application is a continuation-in-part of and claims priority under 35 U.S.C. § 120 from PCT Application No. PCT/EP2021/071490, filed on Jul. 30, 2021, the entire contents of which are incorporated herein by reference.

### TECHNICAL FIELD

The present invention relates to the field of determining at least one optical property of at least one deposition material used for a lithographic mask. In particular, the at least one deposition material can be used in a repair process of a lithographic mask having at least one clear defect.

### BACKGROUND

As a result of the constantly increasing integration density in the semiconductor industry, lithographic or photolithographic masks have to project smaller and smaller structures onto a photosensitive layer, i.e., a photoresist dispensed on a wafer. In order to fulfil this demand, the exposure wavelength of lithographic masks has been shifted from the near ultraviolet across the mean ultraviolet and the deep ultraviolet (DUV) into the extreme ultraviolet (EUV) region of the electromagnetic spectrum. Presently, mainly a DUV wavelength of 193 nm is used for the exposure of the photoresist on wafers. But the application of photolithographic exposure systems operating in the EUV wavelength range (approximately in a range of 10 nm to 15 nm) rapidly gains importance. As a consequence, the manufacturing of photolithographic masks having ever smaller pattern elements is becoming more and more complex, and thus more and more expensive as well.

Typically, defect-free photolithographic masks cannot be fabricated with a reasonable yield due to their tiny pattern elements. The defects of photomasks must be corrected at the end of the manufacturing process whenever possible. In transmissive photomasks, the exposure radiation typically incidents on the mask symmetrically with respect to the optical axis of the mask. This means that a CRA (chief ray angle) is zero. The situation changes when using reflective lithographic masks. To separate the incident and the reflective radiation, radiation (e.g., EUV radiation) incidents on a reflective mask typically with a CRA in a range of 5° to 8° with respect to the optical axis. As a consequence, three-dimensional (3D) effects play an important role when optimizing the operational behaviour of an EUV mask. Exemplary 3D effects are shadowing, dependence of the CD (critical dimension) on the feature orientation, best focus shift of different pattern elements, just to name a few. For example, shadowing effects of an absorbing layer can be minimized when reducing the layer thickness or layer height of the absorbing layer as much as possible. But, on the other hand, the function of the absorbing layer may not be compromised so that, for example, the optical contrast in the photoresist arranged on a wafer does not deteriorate.

For precisely determining an optimal layer thickness of an absorbing layer, it is necessary to know the optical properties of the material used for absorbing the EUV photons. However, it is challenging to determine the optical properties of very thin layers, that is layers having a height or thickness as well as lateral dimensions in the two-digit nanometer range. In the article “Validation of optical constants in the EUV wavelength range,” Proc. SPIE 11147, Intern. Conf. on Extreme Ultraviolet Lithography, Sep. 26, 2019, https://doi.org/101117/12.2536644, the authors Q. Saadeh et al. describe using EUV reflectometry for determining the optical constants for candidate materials for EUV photomask absorbers. Further, the authors N. Davidova et al. describe in the article “Experimental approach to EUV imaging enhancement by mask absorber height optimization,” 29th European Mask and Lithography Conference, edited by U.F.W. Behringer and W. Maurer, Proc. of SPIE, 2013, Vol. 8886, p. 88860A1-88860-A15, an EUV lithography performance improvement by optimizing and fine-tuning an EUV mask, in particular by optimizing a height of the absorbing layer. The authors of both publications describe using radiation of a synchrotron source for measuring the refractive index and the absorption constant of an absorbing layer. However, a synchrotron source is not a common metrology tool in the semiconductor industry. This means, the respective measurements must be executed externally, and they typically require large samples surfaces.

The situation is getting worse if the absorbing material is not used for fabricating EUV masks but is used for correcting clear defects of a reflective photomask. In a photomask repair process the material composition of a deposition material cannot be controlled as precisely as in a photomask fabrication process. This may result in a variation of the composition of the deposited material. Consequently, the optical properties of the deposited material may also vary. Thus, it is even more important for repair processes of reflective lithographic masks to precisely know the optical properties of the deposition material in order to be able to reliably correct defects of reflective photomasks.

It is therefore one aspect of the present invention to provide a method and apparatuses for optimizing the determination of optical properties of deposition materials used for lithographic masks.

### SUMMARY

According to a first aspect of the invention, a method according to claim 1 and apparatuses according to claims 18 and 19 are provided for solving the above problem at least partly.

In a first embodiment, a method for determining at least one optical property of at least one deposition material used for a for lithographic mask comprises the steps: (a) determining a height value of the at least one deposition material deposited on a substrate for each of at least three different deposition heights of the deposition material, wherein the at least three different deposition heights are in a nanoscale range; (b) determining a reflectivity value of the at least one deposition material for each of the at least three different deposition heights, wherein determining the reflectivity values comprises using photons generated by an optical inspection system; and (c) determining the at least one optical property of the at least one deposition material by adapting simulated reflectivity data to the measured reflectivity values for each of the at least three different deposition heights.

An optical inspection system may be any metrology system which may be used for inspecting, reviewing, and/or verifying a lithographic mask and/or a wafer. In particular, the optical inspection system may use an aerial image measuring principle.

Typically, numerical values of optical properties of very thin layers having specific material compositions and/or densities are not known with sufficient accuracy in the DUV and EUV wavelength range, or are not known at all, in order to optimize a layer thickness of an absorbing layer of a reflective photomask. The inventive method determines reflectivity values for three or more different deposition heights by using photons, preferably photons of the actinic wavelength of the lithographic mask. Hence, the determined at least one optical property of the at least one deposition material is obtained at the condition, the lithographic mask is later subjected to. Further, it avoids the execution of measurements by using metrology tools which are uncommon in the semiconductor industry and may exclusively be based on metrology tools which are available in the semiconductor industry. Moreover, since photons can usually be controlled well in lithographic metrology tools, as for example optical inspection systems, small (lateral) sample sizes may be sufficient according to the aspects outlined herein. Furthermore, optical inspection systems are well established in the semiconductor industry and are more compact as for example synchrotron sources.

Moreover, the inventive method varies a numerical value of the at least one optical property to adapt simulation data to experimental values in order to determine the at least one optical property with a highest possible accuracy. Hence, it uses a combination of experiments and simulations for simultaneously optimizing both the accuracy with which the at least one optical property is determined and the effort necessary for obtaining the result.

For example, if accuracy is needed only to a more limited extent, one or more values may be used instead of three or more. For example, a height value of the at least one deposition material may be determined for one or more deposition heights of the deposition material, wherein the at least three different deposition heights are in a nanoscale range. A reflectivity value may be determined for each of the one or more different deposition heights, wherein determining the reflectivity values comprises using photons generated by an optical inspection system. The at least one optical property may be determined by adapting simulated reflectivity data to the measured reflectivity value(s) for each of the one or more different deposition heights.

For example, one or more values may be used and at the same time higher accuracy may be achieved, if one or more optical properties of the at least one deposition material is already known. Then the known optical property may be used for partly determining the simulated reflectivity data that is then adapted to the measured reflectivity value(s) to determine at least one other optical property.

Determining the height values of the at least one deposition material may comprise measuring the height values of the at least one deposition material. Determining the height values may also comprise determining the height values based on calibration data. For example, a height value may be determined based on a number of deposition steps and/or a deposition time (and calibration data linking the steps and/or time to a deposition height value).

Additionally, or alternatively, determining the reflectivity values of the at least one deposition material may comprise measuring the reflectivity values of the at least one deposition material using photons generated by an optical inspection system.

The method described above may obtain or receive deposition height values from a first metrology tool. Further, the method may also obtain measured reflectivity values from an external metrology tool. Thus, the method may perform simulations and may determine the at least one optical property by comparing simulated reflectivity data and measured reflectivity values. However, it is also possible that the method performs both types of experiments and the simulations. Moreover, it is also conceivable that the method executes a first portion of the experiments and obtains experimental data for a second portion of the experiments or vice versa.

Determining the at least one optical property may comprise determining at least one of the at least one deposition material: a refractive index or an absorption constant.

Apart from the composition of a material, its density may also have an impact on the at least one optical property. Further, the substrate on which a material is deposited may influence the at least one optical property of a thin layer of the deposited material. Moreover, presently available materials used for fabricating lithographic masks for the EUV wavelength range show a refractive index which is <1. Further, at the moment, there are no materials available which are essentially optically transparent in the EUV wavelength range. This means that the absorption constant of presently known materials is larger than zero.

Determining the at least one optical property may comprise determining the at least one optical property at an actinic wavelength of the lithographic mask.

This feature may ensure that the at least one optical property is measured under essentially identical conditions the lithographic mask is operated later in a semiconductor factory (wafer fab). It is an advantage of the method described in this application that the at least one optical property is measured essentially under the conditions the lithographic mask is operated at a later time.

Within this application, the term “essentially” means measuring results obtained at different sites when using state of the art metrology tools.

The deposition material may comprise an absorbing material. The absorbing material may have a relatively large absorption constant in the extreme ultraviolet wavelength range. Such a large absorption constant (k) may have a numerical value in the extreme ultraviolet wavelength range which is k>0.05.

The substrate may comprise a substrate of a lithographic mask for the extreme ultraviolet wavelength range having a multilayer structure and may further comprise depositing the at least one deposition material on the multilayer structure. It is also possible to use any substrate for depositing the deposition material. Further, it is also conceivable to deposit a specific layer on any substrate which provides an optical interface which is essentially identical to the surface on which the at least one deposition material is deposited (e.g., on a lithographic mask).

A top surface of the deposition heights of at least one deposition material may comprise an area of equal to or less than: 64 μm², preferably 16 μm², more preferred 4 μm², even more preferred 1 μm², and most preferred 0.5 μm².

It is a beneficial effect of the described method that the various deposition heights of the at least one deposition material may have a small area on which the reflectivity data can be measured. Thus, the effort of depositing the various deposition heights is rather low. In contrast to this, measuring the reflectivity data by use of a synchrotron source comprises depositing areas of the at least one deposition material which are approximately larger by a factor of 100. Further, small volumes of deposition materials may be deposited by using a particle beam induced deposition process. Therefore, deposition materials may be generated having a material composition which is very close to the deposition material used for repairing clear defects of lithographic masks.

The nanoscale range may comprise deposition heights of the at least one deposition material of: <200 nm, preferred<150 nm, more preferred<100 nm, and most preferred<80 nm.

For thick absorbing layers (layer thickness>100.2) the reflectivity of an absorbing layer is exclusively determined by the absorption constant of the deposition material. However, for smaller thickness values, particularly in the nanoscale range or nanoscale wavelength range, the reflectivity behavior of an absorbing layer also depends on the thickness or height of the absorbing layer. A portion of the incident radiation is reflected at the front surface and another portion is reflected at the rear surface of the absorbing layer. This may result in an interference effect of the electromagnetic radiation reflected from the absorbing layer. As a consequence, a swing curve is superimposed over the reflectivity curve that generally decreases as a function of the height of the absorbing layer in the nanoscale range.

The periodicity of the swing curve for a CRA in a range of 5° to 8° is approximately

$$h \approx \frac{λ}{2 \cdot n} ( integer + \frac{1}{2} ) ,$$

wherein h is the height or thickness of the absorbing layer, A given by:

stands for the wavelength (e.g., the actinic wavelength of the lithographic mask), and n denotes the refractive index of the absorbing layer. Please note that the above approximation does not include the effect of the off-axis incidence of the actinic radiation. In order to find a minimum height of an absorbing layer which fulfills a predetermined amount of absorption, the interference between the front and the rear surface must be considered.

There is a second interference effect which impacts on the performance of a reflective photomask. The actinic radiation reflected from the multilayer structure (BF, bright field) interferes with the radiation reflected from the absorbing layer (DF, dark field). The image contrast generated by the pattern elements of a reflective mask is maximized if the two reflected contributions have a phase difference of 180°. This requirement may be fulfilled if:

$$h \approx \frac{λ}{4 \cdot ( 1 - n )} .$$

Both interference effects dependent on the refractive index n of the absorbing layer. In particular, the BF/DF contribution strongly depends on the refractive index. Hence, the refractive index of the material of the absorbing layer must be known with high precision to calculate a suitable optical height of the absorbing layer. The aspects described herein harness these effects to precisely determine the optical properties of the deposition material.

The at least three different height values of the at least one deposition material may comprise at least 10, preferably at least 20, more preferred at least 30, and most preferred at least 40 different height values of the at least one deposition material.

The height values of the at least one deposition material may comprise a range of 1 nm to 150 nm, preferred 2 nm to 100 nm, more preferred 5 nm to 80 nm, and most preferred 10 to 60 nm.

An overall height difference of the at least three different deposition heights may be larger than a wavelength of the photons used for determining the reflectivity values.

To determine the periodicity of the swing curve superposed on the reflectivity curve, it may be helpful that the height range spanned by the at least three deposition heights is larger than a wavelength of the photons used for measuring the reflectivity values. For example, the overall height difference may be understood as the difference between the largest height value and the smallest height value of the at least three different deposition heights.

A height difference between the at least three different deposition heights may not have a periodicity of a half wavelength, or integer multiples thereof, of the photons used for determining the reflectivity values. If the depositions heights have such a periodicity, the period of the swing curve superposed on the reflectivity curve may not be detected reliably. In other examples, a height difference between two, in particular between two adjacent, deposition heights may not have a value of half the wavelength or integer multiples thereof.

The photons may comprise photons of the extreme ultraviolet wavelength range.

As already indicated above, by using photons having essentially the wavelength range of the photons which illuminate the lithographic mask in its operation mode, the at least one optical property can be measured with high precision.

The lithographic mask may comprise at least one clear defect. The deposition material may be used to repair the at least one clear defect. The lithographic mask may comprise a lithographic mask for the EUV wavelength range. In some examples, the method described herein may be implemented with the substrate of the mask whose defect is to be repaired. However, it is also possible to use it with a substrate, and then deposit the deposition material on the mask to be repaired with an (optimum) height calculated based on the determined one or more optical properties.

The photons may comprise photons of an actinic wavelength of the lithographic mask. The optical inspection system may comprise at least one of: an inspection system for the lithographic mask, an aerial image metrology system, an optical scanning microscope, or a microscope. Each of these may use an actinic wavelength of the lithographic mask.

An inspection system for inspecting masks in the deep ultraviolet (DUV) wavelength range may use a laser source as a light source for inspecting lithographic masks. An inspection system for inspecting masks in the EUV wavelength range may use a plasma source as a light source for inspecting lithographic masks. The plasma may be generated by using pulses of a laser system as an energy source of high density.

An aerial image metrology system may use a scanner of a lithographic exposure system but replace the projection lens with a magnifying objective which images a small section of the intensity distribution of the mask on a camera with high resolution.

Determining the reflectivity values may comprise using an optical inspection system for the extreme ultraviolet (EUV) wavelength range. The optical inspection system for the EUV wavelength range may be an aerial image metrology system for the EUV wavelength range (EUV aerial image metrology system).

The method may further comprise the step of determining a deposition height function by interpolating between the at least three measured deposition heights.

The method may further comprise the step of plotting the measured reflectivity values as a function of the height values of the at least one deposition material. The method may further comprise the step of plotting the measured reflectivity values as a function of the deposition height.

Measuring the deposition heights of the at least one deposition material may comprise using at least one of: a scanning probe microscope and a profilometer. The scanning probe microscope may be of any type of a scanning probe microscope.

The method may further comprise the step of depositing the at least one deposition material for the at least three deposition heights on the substrate.

The substrate may be prepared by depositing a layer providing an optical interface of the surface on which the at least three different height values of the at least one deposition material are deposited. The optical interface may be adapted essentially as an optical interface of the lithographic mask on which the deposition material may be deposited for repairing a clear defect, for example.

Depositing the at least one deposition material may comprise performing a particle beam induced deposition process using at least one precursor gas. The at least one deposition gas may comprise at least one element from the group of: a metal alkyl, a transition element alkyl, a main group alkyl, a metal carbonyl, a transition element carbonyl, a main group carbonyl, a metal alkoxide, a transition element alkoxide, a main group alkoxide, a metal complex, a transition element complex, a main group complex and an organic compound.

The metal alkyl, the transition element alkyl and the main group alkyl may comprise at least one element from the group of: cyclopentadienyl (Cp) trimethyl platinum (CpPtMe₃), methylcyclopentadienyl (MeCp) trimethyl platinum (MeCpPtMe₃), tetramethyltin (SnMe₄), trimethylgallium (GaMe₃), ferrocene (Cp₂Fc) and bisarylchromium (Ar₂Cr).

The metal carbonyl, the transition element carbonyl and the main group carbonyl may comprise at least one element from the group of: chromium hexacarbonyl (Cr(CO)₆), molybdenum hexacarbonyl (Mo(CO)₆), tungsten hexacarbonyl (W(CO)₆), dicobalt octacarbonyl (Co₂(CO)₈), triruthenium docadecarbonyl (Ru₃(CO)₁₂) and iron pentacarbonyl (Fe(CO)₅).

The metal alkoxide, the transition element alkoxide and the main group alkoxide may comprise at least one element from the group of: tetraethyl orthosilicate (TEOS, Si(OC₂H₅)₄) and tetraisopropoxytitanium (Ti(OC₃H₇)₄). The metal halide, the transition element halide and the main group halide may comprise at least one element from the group of: tungsten hexafluoride (WF₆), tungsten hexachloride (WC₁₆), titanium hexachloride (TiCl₆), boron trichloride (BC₁₃) and silicon tetrachloride (SiCl₄).

The metal complex, the transition element complex and the main group complex may comprise at least one element from the group of: copper bis(hexafluoroacetylacetonate) (Cu(C₅F₆HO₂)₂) and dimethylgold trifluoroacetylacetonate (Me₂Au(CsF₃H₄O₂)).

The organic compound may comprise at least one element from the group of: carbon monoxide (CO), carbon dioxide (CO₂), an aliphatic hydrocarbon, an aromatic hydrocarbon, a constituent of vacuum pump oils and a volatile organic compound.

Further, the particle beam induced deposition process may comprise at least one additive gas. The at least one additive gas may comprise at least one element from the group of: an oxidation agent, a halide, and a reducing agent.

The oxidation agent may comprise at least one element from the group of: oxygen (O₂), ozone (O₃), water vapor (H₂O), hydrogen peroxide (H₂O₂), dinitrogen oxide (N₂O), nitrogen oxide (NO), nitrogen dioxide (NO₂) and nitric acid (HNO₃). The halide may comprise at least one element from the group of: chlorine (Cl₂), hydrochloric acid (HCl), xenon difluoride (XeF₂), hydrogen fluoride (HF), iodine (I₂), hydrogen iodide (HI), bromine (Br₂), hydrogen bromide (HBr), nitrosyl chloride (NOCl), phosphorus trichloride (PCl₃), phosphorus pentachloride (PCl₅) and phosphorus trifluoride (PF₃). The reducing agent may comprise at least one element from the group of: hydrogen (H₂), ammonia (NH₃) and methane (CH₄).

The particle beam may be an electron beam. The additional gas may support the deposition process. In particular, the additional gas may help so that the at least one deposition material has a predetermined material composition.

The at least one precursor gas may comprise chromium hexacarbonyl (Cr(CO₆)) and the additional gas may comprise nitride dioxide (NO₂).

The at least one deposition material may comprise chromium oxide (CrₓO_{y}), wherein x and y may vary within ranges of: 0<x<1.5 and 0<y<3.

The at least one deposition material may further comprise a carbon portion of <30 atom-%, preferred<20 atom-%, more preferred<10 atom-%, and most preferred<5 atom-%.

Determining the at least one optical property may comprise determining a deposition height function from the at least three different deposition heights and may further comprise simulating reflectivity data for the at least one deposition material as a deposition height function of the at least one deposition material. The deposition height function may for example indicate a deposition height as a function of deposition steps.

Simulating reflectivity data may comprise taking a numerical value of the at least one optical property of the at least one deposition material (or of a similar material) of the literature as a starting value. Simulating reflectivity data may comprise calculating at least one reflectivity curve as a function of the deposition height (and, e.g., the refractive index and absorption constant), by using a simulation tool which numerically solves Maxwell's equations. Dr.LITHO is an exemplary simulation tool which can be used for simulating reflectivity curves as a function of the height or thickness of an absorbing layer. Examples of further simulation tools which can also be used are: PROLITH, ProLE and HiperLith.

Adapting the simulated reflectivity data to the measured reflectivity values may comprise varying the at least one optical property of the at least one deposition material and may further comprise simulating the reflectivity data as a function of the deposition height. Varying the at least one optical property may comprise varying at least one numerical value of the at least one optical property.

Adapting the simulated reflectivity data to the measured reflectivity values may comprise comparing simulated reflectivity data of various simulation runs having different numerical values of the at least one optical property with the measured reflectivity values.

The method defined above relies on experimental data and adapts simulated data or simulated curves to the experimental data by systematically varying at least one numerical value of the at least one optical property.

Determining the at least one optical property may comprise extracting the at least one optical property from simulated reflectivity data having a best fit to the measured reflectivity values.

The method defined above may further comprise the step of calculating an (optimal) deposition height of the at least one deposition material based on the determined at least one optical property in order to correct at least one clear defect of the lithographic mask.

By precisely measuring the at least one optical property of the at least one deposition material, an absorbing layer may be fabricated which fulfils the predetermined absorption properties of the lithographic mask and at the same time minimizes 3D effects of the lithographic mask.

In some examples, the method may further comprise the step of depositing the at least one deposition material on a lithographic mask with the calculated (optimal) deposition height, to correct the at least one clear defect.

A computer program may have instructions to perform any of the method steps of the above discussed aspects when the computer program is executed on a computer system.

Another aspect relates to a lithographic mask whose at least one defect is repaired according to any of the method steps of the above-described aspects.

In a further embodiment, a computing apparatus may be provided for determining at least one optical property of at least one deposition material used for a lithographic mask. The computing apparatus may be operable to: (a) determine a height value of at least one deposition material for each of at least three different deposition heights, wherein the at least three different deposition heights are in a nanoscale range; (b) determine a reflectivity value of the at least one deposition material for each of the at least three deposition heights, wherein the reflectivity values are measured by using photons generated by an optical inspection system; and (c) determine the at least one optical property of the at least one deposition material by adapting simulated reflectivity data to the obtained reflectivity values for the at least three different deposition heights. In some examples, the computing apparatus may be operable to obtain a starting value for the at least one optical property of the at least one deposition material, before performing step (c).

The computing apparatus may be further operable to at least two times simulate reflectivity data for different numerical values of the at least one optical property as a function of a deposition height for photons having essentially the same wavelength distribution as the photons used for measuring the reflectivity values. The computing apparatus may be further operable to compare the at least two simulated reflectivity data sets with the measured reflectivity values. Further, the computing apparatus may be operable to extract the at least one optical property from a simulated reflectivity data set having a best fit to the measured reflectivity values.

In another embodiment, an apparatus for determining at least one optical property of at least one deposition material for a lithographic mask, comprises: (a) means for determining a height value of the at least one deposition material deposited on a substrate for each of at least three different deposition heights, wherein the at least three different deposition heights are in a nanoscale range; (b) means for measuring a reflectivity value of the at least one deposition material for each of the at least three different deposition heights, wherein measuring the reflectivity values comprises using photons generated by an optical inspection system; and (c) means for determining the at least one optical property of the at least one deposition material by adapting simulated reflectivity data to the measured reflectivity values for each of the at least three different deposition heights.

The means for determining a height value may comprise means for measuring a height value, e.g., at least one of a scanning probe microscope, and a profilometer. The scanning probe microscope may comprise an AFM (atomic force microscope), an STM (scanning tunnelling microscope), an MFM (magnetic force microscope), a SNOP (scanning near-field optical microscope), or a SNAM (scanning near-field acoustic microscope). A profilometer may use a contact (tactile) or a contactless measurement principle. A stylus or a mechanical profilometer may use diamond stylus for scanning a surface, for example the surface of a lithographic mask. Non-contact profilometers typically use an optical method, as for example an interferometric, a holographic, a confocal, or white light technique, for determining a surface contour. Correspondingly, an interferometer, a hologram, confocal lenses, or a white light source may be provided.

The means for measuring a reflectivity value of the at least one deposition material for each of the at least three different deposition heights may comprise an optical inspection system, in particular an optical lithographic inspection system. The optical inspection system may comprise at least one of an AIMS® (aerial image metrology system) using photons essentially having the actinic wavelength of the lithographic mask, an inspection system for the lithographic mask, an ultraviolet microscope, or an x-ray microscope.

The means for determining a height value may also comprise determining the height value based on calibration data. For example, a height value may be determined based on a number of deposition steps and/or a deposition time (and calibration data linking the steps and/or time to a deposition height value).

An optical inspection system may comprise a light source. The light source may be a laser light source, for example emitting in the DUV wavelength range, and/or a plasma light source, for example generating photons in the EUV wavelength range. The plasma light source may comprise a laser source for heating metal droplets. The metal droplets may comprise tin droplets and heating metal droplets may comprise vaporizing metal droplets.

The optical inspection system may further comprise at least one optical element operable to guide and focus light generated by the light source onto a lithographic mask and/or a wafer. The at least one optical element may have a numerical aperture which is large enough so that the at least one optical element can image the deposition material having a predetermined lateral size. The at least one optical element may generally image the deposition material of predetermined lateral size if it fulfils Raleigh's resolution criterion. This means, if d is the smallest lateral dimension of the deposition material and λ is the wavelength of the optical inspection system, the minimum numerical aperture (NA) is given by: NA=1.22·λ/d. This means, the lateral size d of the deposition material determines the minimum NA required by the optical inspection system to resolve the deposition material. To resolve the deposition material, it is necessary for the numerical aperture of the at least one optical element to be: NA>1.22·λ/d. preferred: NA>2·1.22·λ/d, and most preferred: NA>4·1.22·λ/d. For example, the smallest lateral dimension may have values of 0.5 μm, 1 μm, 2 μm, 4 μm, or 8 μm (for example using quadratic, rectangular (circular), etc. deposition geometries with corresponding edge lengths (diameters), respectively). For λ, a typical (for EUV) value may be an actinic wavelength of 13.5 nm. Hence, the numerical aperture NA may be directly linked to a minimum lateral dimension of the deposition geometry for each wavelength, for example λ=13.5 nm. For example, for a lateral dimension of 1 μm (and)=13.5 nm), the minimum numerical aperture NA may be 0.016, preferred 0.033, most preferred 0.066. For example, for a lateral dimension of 0.5 μm (and λ=13.5 nm), the minimum numerical aperture NA may be 0.033, preferred 0.066, most preferred 0.132. For other lateral dimensions as outlined herein (cf. above), minimum numerical aperture values can be obtained in the same manner (and are understood as part of the present disclosure).

The lithographic mask may be arranged on a mask stage. Instead of a mask, a substrate may be arranged on the mask stage which comprises at least one deposition material having at least three different deposition heights.

Moreover, the optical inspection system may, but needs not, comprise a further optical element, e.g., a projection lens, operable to focus light reflected from the lithographic mask into a detector. The detector may be a CCD (charge-coupled device) camera. The projection lens may be a magnifying projection lens. The magnification of the projection lens may be >50, preferred>100, more preferred>200, and most preferred>400.

The optical inspection system may comprise an optical inspection system for the EUV wavelength range. In particular, the aerial image metrology system may comprise an aerial image metrology system for the extreme ultraviolet wavelength range (EUV aerial image metrology system).

The apparatus may be operable to perform any of the method steps of the aspects described above.

### BRIEF DESCRIPTION OF DRAWINGS

In order to better understand the present invention and to appreciate its practical applications, the following figures are provided and referenced hereafter. It should be noted that the figures are given as examples only and in no way limit the scope of the invention.

FIG. 1 schematically shows an overview of the method applied to determine an optical property of an absorbing layer of a reflective lithographic mask;

FIG. 2 schematically represents a top view of deposition material deposited on a substrate;

FIG. 3 schematically depicts measured height values as a function of the number of deposition steps used for depositing the deposition material;

FIG. 4 schematically illustrates the principle of an aerial image metrology system on the basis of a lithographic exposure system as an example of an optical inspection system;

FIG. 5 schematically presents measured reflectivity values and simulated reflectivity data as a function of the deposition height of an absorbing layer;

FIG. 6 depicts a flow diagram of a method for determining at least one optical property of at least one deposition material used for a lithographic mask; and

FIG. 7 schematically illustrates an apparatus which can be used for executing the method presented in FIG. 1.

### DETAILED DESCRIPTION

In the following, the present invention will be more fully described hereinafter with reference to the accompanying figures, in which exemplary embodiments of the invention are illustrated. However, the present invention may be embodied in different forms and should not be construed as limited to the embodiments set forth herein. Rather, these embodiments are provided so that this disclosure will be thorough and will convey the scope of the invention to persons skilled in the art.

In the following, the present invention is described by taking absorbing reflective lithographic masks as examples. However, the present invention can also be applied to phase-shifting reflective masks. Further, the method described in the present application may also be used for determining optical properties of deposition materials of transmissive photomasks. The optical properties of deposition materials of transmissive photomasks may be determined by performing transmission and/or reflection measurements. The following detailed description is restricted to measuring reflectivity data.

Apart from photomasks, the presented method may be used for determining optical properties of very thin layers deposited on various kinds of optical elements as for example mirrors and/or lenses. Generally, the present invention may be applied for determining optical properties of materials used for forming very thin layers in which interference effects must be considered.

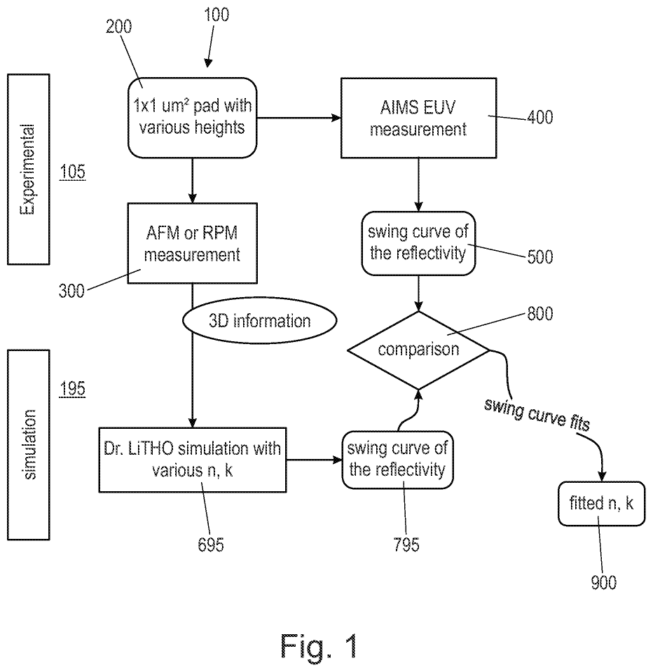

FIG. 1 schematically provides an overview of the method presented in the present application. FIG. 1 contains two parts. The upper part 105 presents the experimental portion of the method 100, and the lower part 195 illustrates the simulation portion of the determination of optical properties of deposition materials.

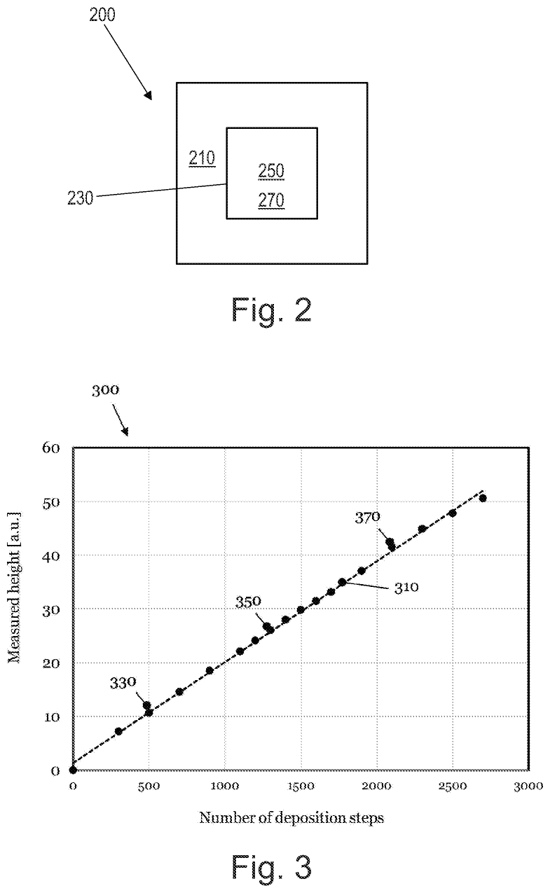

In the following, the various parts of the method 100 are described in detail. In a first step of the experimental part, deposition material is deposited on a substrate having various height values. Diagram 200 of FIG. 2 depicts a top view on a substrate 210 on which deposition material 250 is deposited having various height values. In the example presented in FIG. 2, the deposited material 250 is deposited in form of a square having dimensions of 1 μm×1 μm. FIG. 2 presents an image recorded with a scanning electron microscope (SEM). The line 230 separates the substrate 210 and the deposited material 250. However, the deposition material 250 may be deposited in various geometric forms of its top surface. For example, the deposition material 250 may be deposited in form of a rectangle, circle, or any geometric shape (not shown in FIG. 2). The top surface 270 of the deposition material 250 may have an area of 1 μm² or even less.

It is an advantage of method 100 that the surface 270 of the deposition material 250 may have a size which is close to the dimensions of clear defects which may be repaired by using the deposition material 250. This allows depositing deposition materials 250 on the substrate 210 by using a particle beam induced deposition process. Thus, the material compositions of the deposition material 250 used for determining the optical properties of the deposition material 250 and of the deposition material 250 used for repairing clear defects may be very similar. For example, the deposition material 250 may be deposited by using an EBID (electron beam induced deposition) process.

In the example presented in FIG. 2, the deposition material 250 is chromium oxide (CrₓO_{y}) with 0<x<1.5 and 0<y<3. But the deposition material 250 is not restricted to chromium oxide. Rather, various metal oxides may be deposited on the substrate 210. Further, apart from metal oxides, for example metal nitrides may be also used as materials for forming thin absorbing layers. Generally, the described method by be applied for the determination of optical properties of coating materials or any materials having a thickness in the nanoscale range.

The substrate 210 may be the upper surface of a multilayer structure of a reflective mask. Alternatively, the substrate 210 may be any substrate, as for example a wafer. If necessary, a layer may be deposited on a substrate 210 which provides an optical interface which is essentially identical to the surface on which the deposition material 250 is deposited for correcting a clear defect of a lithographic mask.

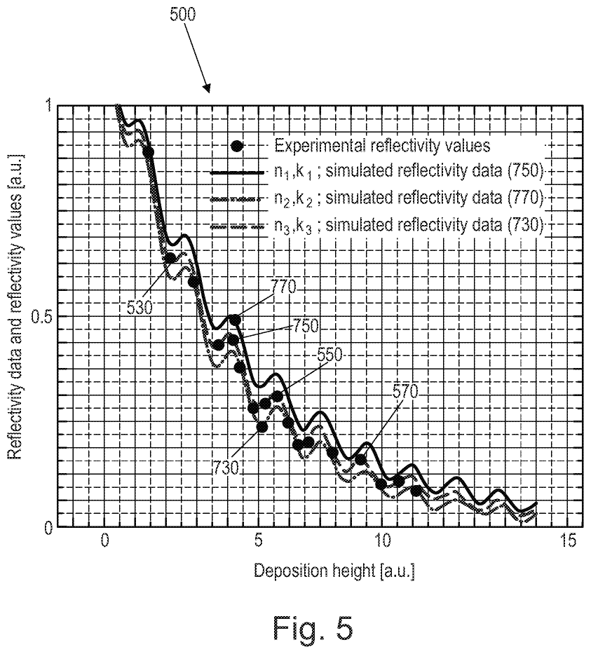

The diagram 300 of FIG. 3 shows a number of height values 330, 350, 370 of the deposition material 250 presented as a function of the number of deposition steps applied for depositing the deposition material 250. The deposition heights 330, 350, 370 of the deposition material 250 linearly increase with the number of deposition steps. The dotted curve 310 provides a normalization curve for comparing measured reflectivity values and reflectivity data simulated as a function of the deposition height (see FIG. 5 below). Therefore, as symbolized in FIG. 1, curve 310 may be an input parameter to the simulation tool 600.

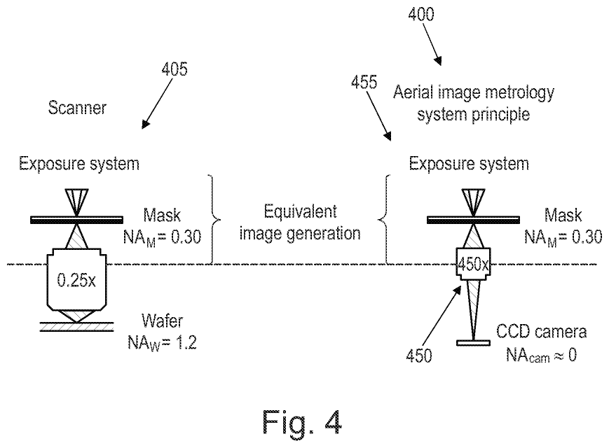

Further, as illustrated by reference sign 400 in FIG. 1, substrate 210 having deposition material 250 with various height values 330, 350, 370 is measured by an optical inspection system. In the example presented in FIG. 1, the optical inspection system is an aerial image metrology system. Diagram 400 of FIG. 4 schematically illustrates the measuring principle of an aerial image metrology system presented in the right partial image 455 in comparison with a lithographic exposure system illustrated on the left partial image 405. An aerial image metrology system is a presently preferred example of an optical inspection system. In a lithographic exposure system, electromagnetic radiation of the actinic wavelength is focused onto a lithographic mask. A projection optical unit or a projection lens images the radiation passing through the photomask with reduction (typically 1:4 or 1:5) on a wafer or on a photoresist distributed on the wafer with a large numerical aperture (NA).

The right partial image 455 in FIG. 4 shows some components of an optical mask inspection system 450 which uses the aerial image metrology system principle. The exposure system of the scanner and of an aerial image metrology system 450 are substantially identical. This means that the image generation, for example of pattern elements of a lithographic mask, is substantially the same for both systems. Thus, the aerial image metrology system 450 images a segment of the optical intensity distribution of a mask such as is incident to a photoresist arranged on the wafer. Unlike in the case of a scanner, however, in the case of the aerial image metrology system 450 a lens images a small segment of the optical intensity distribution of a photomask with great magnification on a CCD (charge-coupled device) camera.

Diagram 455 of FIG. 4 shows an aerial image metrology system 450 for a transmissive photomask. An EUV aerial image metrology system adapts the aerial image measurement principle to reflective lithographic masks (not shown in FIG. 4). By using an EUV aerial image metrology system as an example of an EUV optical inspection system, it becomes possible to measure the reflectivity values of the deposition material 250 having deposition heights 330, 350, 370 in the two-digit nanometer range with very high resolution.

Diagram 500 of FIG. 5 presents the reflectivity values 530, 550, 570 measured by the EUV acrial image metrology system discussed in the context of FIG. 4. In FIG. 5, the reflectivity values 530, 550, 570 are depicted as bullets. The measured reflectivity values 530, 550, 570 cover height values 330, 350, 370 of several wavelengths of the EUV aerial image metrology system or more general of the EUV optical inspection system. Further, the height difference between different height values 330, 350, 370 is not equidistant but is randomly selected to avoid that the height difference accidentally coincides with the periodicity of the wavelength of the EUV photons of the optical inspection system, for example the aerial image metrology system of FIG. 1. It can be clearly recognized from FIG. 5 that the measured reflectivity values 530, 550, 570 do not strictly monotonically decrease or fall as a function of the deposition height 330, 350, 370 of the absorbing deposition material 250. This means the EUV aerial image metrology system can clearly detect the swing curve superposed on the reflectivity curve falling as a function of the deposition height 330, 350, 370 of the deposition material 250.

Again, with respect to FIG. 1, the lower partial image 195 of diagram 100 symbolizes the simulation portion of the method described in the present application. The dotted curve 310 of FIG. 3 may be provided as an input parameter to the simulation tool 600. The curve 310 forms the x-axis for simulating the reflectivity of the deposition material 250 as a function of the deposition height 330, 350, 370. Further, input parameters to the simulation tool 600 may be 3D information of the deposition material 250 to be simulated.

The simulation tool 695 numerically solves Maxwell's equations for discrete deposition heights 330, 350, 370 or thicknesses of the deposition material 250. Typically, the refractive index n and the absorption constant k specify the optical properties of a deposition material 250. For performing a useful simulation of the reflectivity behavior of the deposition material 250, numerical values of n and k are required as starting or initial values. Numerical values of n and k of the literature are used for the deposition material 250. If no data are available for a specific deposition material, numerical values of n and k are used for a deposition material having a material composition which is close to deposition material 250 to be investigated.

In the example presented in FIG. 1, the simulation tool Dr.LITHO 695 is used for simulating the reflectivity behavior of the deposition material 250 as a function of the deposition height 330, 350, 370. However, the simulation part 195 can be performed by any conventional simulation tool which numerically solves Maxwell's equations. For example, the simulation tool PROLITH is an alternative to the software package Dr.LITHO.

To determine the optical properties n and k of the deposition material 250, the reflectivity as a function of the deposition height 350 is repeatedly simulated, wherein the starting values of n and k are systematically varied as indicated by the reference sign 795 in FIG. 1. The simulated reflectivity curves for various n and k combinations are presented in FIG. 5 as reflectivity data 730, 750 and 770. As expected, the simulated reflectivity data 730, 750, 770 predict a sharp drop of the reflectivity with increasing height of the deposition material 250. Further, the simulated reflectivity data 730, 750, 770 reveal a swing curve superposed on the reflectivity drop.

As indicated by the reference sign 800 in diagram 100 of FIG. 1, the various simulated reflectivity data 730, 750, 770 or reflectivity data sets 730, 750, 770 are compared with the measure reflectivity values 530, 550, 570. In the example presented in FIG. 5, the reflectivity data 750 best fit to the reflectivity values 530, 550, 570. The reflectivity data 750 are simulated with a refractive index of n=n and an absorption constant of k=k1.

Thus, as symbolized by the reference sign 900 in FIG. 1, the requested optical properties of the deposition material 250 are n=n₁ and k=k1. It is also possible to determine either the refractive index or the absorption constant if the other quantity of the deposition material 250 is already known with high accuracy.

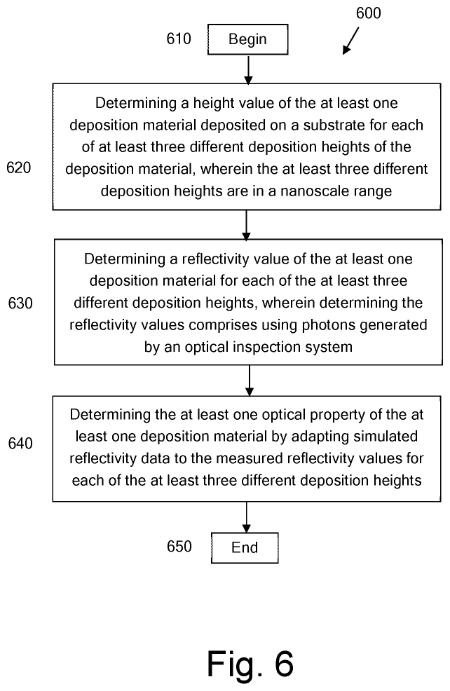

FIG. 6 presents a flow diagram 600 of the method for determining at least one optical property of at least one deposition material 250 used for a lithographic mask. The method begins at 610. At step 620, a height value of the at least one deposition material 250 deposited on a substrate 210 is determined for each of at least three deposition heights 330, 350, 370 of the deposition material 250, wherein the at least three deposition heights 330, 350, 370 are in a nanoscale range. For example, the deposition height 330, 350, 370 may be measured by an AFM or it may be determined based on a number of deposition steps, e.g., as outlined with reference to FIG. 3.

At step 630, a reflectivity value 530, 550, 570 of the at least one deposition material 250 is determined for each of the at least three different deposition heights 330, 350, 370, wherein the determination of the reflectivity values 530, 550, 570 comprises the usage of photons generated by an optical inspection system, in particular of photons of the EUV wavelength range. The reflectivity values 530, 550, 570 may be measured by using an AIMS™ EUV of the applicant.

At step 640, at least one optical property of the at least one deposition material 250 is determined by adapting simulated reflectivity data 730, 750, 770 to measured reflectivity values 530, 550, 570 for each of the at least three different deposition heights 330, 350, 370. This method step may be performed by a computing apparatus. Then the method ends at 650.

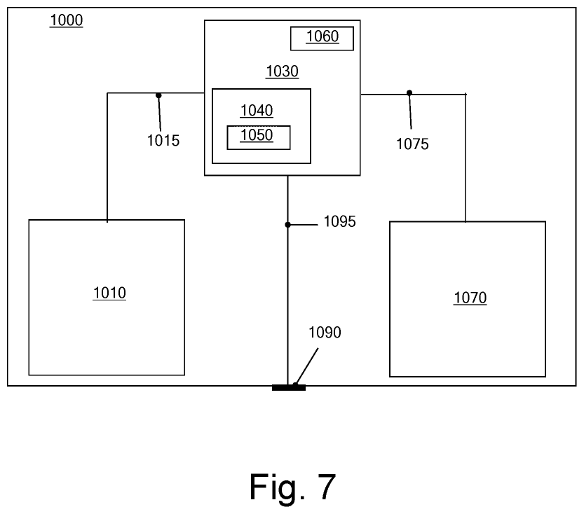

Finally, FIG. 7 schematically depicts an apparatus 1000 which can be used for performing the method schematically presented in FIG. 1. The apparatus 1000 may combine an AFM 1010, as an example of a scanning probe microscope, a computing apparatus 1030 and/or an EUV aerial image metrology system 1070, as an example of an optical inspection system. The computing apparatus 1030 may be connected to the AFM 1010 via the connection 1015. The computing apparatus 1030 may control the AFM 1010 via the connection 1015 and may obtain measuring data, in particular deposition heights 330, 350, 370 from the AFM 1010.

The computing apparatus 1030 may comprise a non-volatile memory 1040 for storing a simulation tool 1050. The simulation tool 1050 may be the simulation tool 695 of FIG. 1. Further, the computing apparatus 1030 may comprise a processor 1060 which is operable to execute instructions of the simulation tool 1050. The hardware implementation of the processor 1060 may be adapted to the requirements of the simulation tool 1050.

The computing apparatus 1030 may be connected to the EUV aerial image metrology system 1070 by use of the connection 1075. The computing apparatus 1030 may control the EUV aerial image metrology system 1070 via the connection 1075. Further, the computing apparatus 1030 may obtain measuring data from the EUV aerial image metrology system 1070 via the connection 1075. In particular, the computing apparatus 1030 may receive reflectivity values 530, 550, 570 from the EUV aerial image metrology system 1070.

The apparatus 1000 may further have an interface 1090. The computing apparatus 1030 of the apparatus 1000 may receive experimental data via the connection 1095 from the interface 1090. The experimental data received by the computing apparatus 1030 via the interface 1090 may comprise depositions heights 330, 350, 370 of the deposition material 250 and/or reflectivity values 530, 550, 570 of the deposition material 250.

In some implementations, each of the optical inspection system and the acrial image metrology system can include a light or radiation source to generate light or radiation, an image sensor (e.g., CCD or CMOS (complementary metal oxide semiconductor) sensor) having an array of individually addressable sensing elements for capturing images of a sample, and optics (e.g., one or more lenses, mirrors or reflecting surfaces, filters, and/or image stops) to direct and/or focus light or radiation from the one or more light or radiation source to the sample, and from the sample to the image sensor. In some implementations, the means for determining the height value can include a deposition tool that performs the deposition of material, in which the deposition tool can include a data processor and a storage device. The data processor in the deposition tool can count and/or measure the number of deposition steps and/or the deposition time. The storage device can store calibration data linking the steps and/or time to a deposition height value. In some implementations, the computing apparatus 1030 can include one or more computers that include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include, e.g., thousands, millions, or billions of transistors.

The processing of data described in this document, such as determining at least one optical property of at least one deposition material by adapting simulated reflectivity data to measured reflectivity values for each of at least three different deposition heights, can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker. In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

The embodiments of the present invention that are described in this specification and the optional features and properties respectively mentioned in this regard should also be understood to be disclosed in all combinations with one another. In particular, in the present case, the description of a feature comprised by an embodiment—unless explicitly explained to the contrary—should also not be understood such that the feature is essential or indispensable for the function of the embodiment.

What is claimed is:

1. A method for determining at least one optical property of at least one deposition material used for a lithographic mask, the method comprising the steps:
a. determining a height value of the at least one deposition material deposited on a substrate for each of at least three different deposition heights of the deposition material, wherein the at least three different deposition heights are in a nanoscale range;
b. determining a reflectivity value of the at least one deposition material for each of the at least three different deposition heights, wherein determining the reflectivity values comprises using photons generated by an optical lithographic inspection system; and
c. determining the at least one optical property of the at least one deposition material by adapting simulated reflectivity data to the measured reflectivity values for each of the at least three different deposition heights.

2. The method of claim 1, wherein determining the height values of the at least one deposition material comprises measuring the height values of the at least one deposition material, and/or wherein determining the reflectivity values of the at least one deposition material comprises measuring the reflectivity values of the at least one deposition material using photons generated by the optical lithographic inspection system.

3. The method of claim 1, wherein determining the at least one optical property comprises determining at least one of: a refractive index or an absorption constant.

4. The method of claim 1, wherein the deposition material comprises an absorbing material.

5. The method of claim 4, wherein a top surface of the deposition heights of the at least one deposition material comprises an area of equal to or less than: 64 μm², preferably 16 μm², more preferred 4 μm², even more preferred 1 μm², and most preferred 0.5 μm².

6. The method of claim 1, wherein the at least three different deposition heights of the at least one deposition material comprises at least 10, preferably at least 20, more preferred at least 30, and most preferred at least 40 different deposition heights of the at least one deposition material.

7. The method of claim 1, wherein an overall height difference of the at least three different deposition heights is larger than a wavelength of the photons used for determining the reflectivity values.

8. The method of claim 1, wherein a height difference between the at least three different deposition heights does not have a periodicity of a half wavelength or integer multiples thereof of the photons used for determining the reflectivity values.

9. The method of claim 1, wherein the photons comprise photons of the extreme ultraviolet wavelength range.

10. The method of claim 9, wherein the optical lithographic inspection system comprises at least one of: an inspection system for the lithographic mask, an aerial image metrology system, an optical scanning microscope, or a microscope that uses an actinic wavelength of the lithographic mask.

11. The method of claim 1, further comprising the step of depositing the at least one deposition material for creating the at least three deposition heights on the substrate.

12. The method of claim 1, wherein adapting the simulated reflectivity data to the measured reflectivity values comprises varying the at least one optical property of the at least one deposition material and simulating the reflectivity data as a function of a deposition height.

13. The method of claim 12, wherein adapting the simulated reflectivity data to the measured reflectivity values comprises comparing simulated reflectivity data of various simulation runs having at least two different numerical values of the at least one optical property with the measured reflectivity values.

14. The method of claim 13, wherein the step of determining the at least one optical property comprises extracting the at least one optical property from simulated reflectivity data having a best fit to the measured reflectivity values.

15. The method of claim 1, further comprising the step of calculating a deposition height of the at least one deposition material based on the determined at least one optical property in order to correct at least one clear defect of the lithographic mask.

16. A computer program having instructions to perform the method steps of claim 1 when the computer program is executed on a computer system.

17. A lithographic mask whose at least one defect is repaired according to the method steps of claim 1.

18. A computing apparatus for determining at least one optical property of at least one deposition material used for a lithographic mask, wherein the apparatus is operable to:
a. determine a height value of the at least one deposition material for each of at least three different deposition heights, wherein the at least three different deposition heights are in a nanoscale range;
b. determine a reflectivity value of the at least one deposition material for each of the at least three deposition heights, wherein the reflectivity values are measured by using photons generated by an optical lithographic inspection system; and
c. determine the at least one optical property of the at least one deposition material by adapting simulated reflectivity data to the determined reflectivity values for the at least three different deposition heights.

19. An apparatus for determining at least one optical property of at least one deposition material for a lithographic mask, comprising:
a. means for determining a height value of the at least one deposition material deposited on a substrate for each of at least three different deposition heights, wherein the at least three different deposition heights are in a nanoscale range;
b. means for measuring a reflectivity value of the at least one deposition material for each of the at least three different deposition heights, wherein measuring the reflectivity values comprises using photons generated by an optical lithographic inspection system; and
c. means for determining the at least one optical property of the at least one deposition material by adapting simulated reflectivity data to the measured reflectivity values for each of the at least three different deposition heights.

20. The apparatus of claim 19, wherein the apparatus is operable to perform the method steps of claim 1.

21. A method comprising:
determining at least one optical property of at least one deposition material used for a lithographic mask having a substrate, wherein the determining the at least one optical property of the at least one deposition material comprises:
receiving measured reflectivity values of at least one deposition material deposited on the substrate of the lithographic mask for at least three different deposition heights of the at least one deposition material, wherein the at least three different deposition heights are in a nanoscale range, and the reflectivity values were measured using photons generated by an optical lithographic inspection system; and
adapting simulated reflectivity data to the measured reflectivity values for each of the at least three different deposition heights.

22. The method of claim 21, comprising determining the reflectivity value of the at least one deposition material for each of the at least three different deposition heights, including:
generating the photons by using the optical lithographic inspection system, and using the photons to measure the reflectivity values.

23. The method of claim 22, comprising determining the height value of the at least one deposition material deposited on the substrate for each of the at least three different deposition heights of the deposition material.

24. The method of claim 21 wherein adapting the simulated reflectivity data to the measured reflectivity values comprises varying the at least one optical property of the at least one deposition material and simulating the reflectivity data as a function of a deposition height.

25. A method for supporting determining at least one optical property of at least one deposition material used for a lithographic mask, the method comprising:
a. determining a reflectivity value of the at least one deposition material for each of at least three different deposition heights, wherein determining the reflectivity values comprises using photons generated by an optical lithographic inspection system, and wherein the at least three different deposition heights are in a nanoscale range; and
b. providing the reflectivity value of the at least one deposition material for each of the at least three different deposition heights for determining the at least one optical property of the at least one deposition material.
